(19) United States
(12) Patent Application Publication
(10) Pub. No.: US 2024/0413059 A1
(43) Pub. Date: Dec. 12, 2024

(54) PACKAGE STRUCTURE AND METHOD FOR FORMING SAME

(71) Applicant: JCET Group Co., Ltd., Wuxi (CN)

(72) Inventors: Lei ZHENG, Wuxi (CN); Ting LIU, Wuxi (CN); Yuesheng ZHANG, Wuxi (CN); Hu PU, Wuxi (CN)

(73) Assignee: JCET Group Co., Ltd., Wuxi (CN)

(21) Appl. No.: 18/736,490

(22) Filed: Jun. 6, 2024

(30) Foreign Application Priority Data
Jun. 6, 2023 (CN) 202310668175.9

(51) Int. Cl. H01L 23/495; H01L 23/00

(52) U.S. Cl. CPC H01L 23/49548; H01L 23/4951; H01L 24/08; H01L 24/48; H01L 24/97; H01L 2224/08145; H01L 2224/08245; H01L 2224/48148; H01L 2224/48245; H01L 2224/97; H01L 2924/0105; H01L 2924/182

(57) ABSTRACT

A package structure and a method are provided. The package structure includes: a die pad; a plurality of discrete leads disposed on either side of or around the die pad, wherein each of the leads includes an upper surface and a lower surface, a trench extending through a portion of the lower surface and a portion of an outer sidewall surface of a lead being formed in a region, away from the die pad, of the lead, a lateral hole being formed in the lead on a side surface of the trench, the lateral hole communicating with the trench to form a step; a first molding layer filling the gaps between the leads and the die pad; a semiconductor chip disposed on an upper surface of the die pad; and a second molding layer disposed on an upper surface of the first molding layer, the lead, and the die pad.

### CROSS-REFERENCE TO RELATED APPLICATION

The present application is based upon and claims priority to Chinese Patent Application No. CN202310668175.9, filed on Jun. 6, 2023, the entire disclosure of which is incorporated herein by reference for all purposes.

### TECHNICAL FIELD

The present disclosure relates to the technical field of semiconductor packaging, and in particular, relates to a package structure and a method for forming the same.

### BACKGROUND

For automobiles, in consideration of current requirements for safety and high reliability, automotive electronic systems require automated visual inspection when chips are packaged. However, in quad flat no-leads package (QFN), by automatic visual inspection, solderable or exposed leads/terminals may not be conveniently observed, making it impossible to confirm whether these leads/terminals are successfully soldered to a printed circuit board (PCB).

To address this issue, a wettable flank process has been developed to improve wetting performance of side leads of QFN and provide a visual indicator of solderability, thereby reducing inspection time.

Conventional wettable flank processes typically create steps on the side of the leads. However, in the conventional packaging process, copper burrs tend to accumulate on the steps during cutting, which affects the soldering space during soldering (or when mounting on the board).

### SUMMARY

Some embodiments of the present disclosure provide a package structure. The package structure includes:

a die pad;

a plurality of discrete leads disposed on either side of or around the die pad, wherein each of the leads includes an upper surface and a lower surface that are opposite to each other, a trench extending through a portion of the lower surface and a portion of an outer sidewall surface of the lead being formed in a region, away from the die pad, of the lead, a lateral hole being formed in the lead on a side surface of the trench, the lateral hole being communicated with the trench to form a step;

a first molding layer filling the gaps between the leads and the die pad;

a semiconductor chip disposed on an upper surface of the die pad, wherein the semiconductor chip is electrically connected to the upper surface of the lead; and

a second molding layer disposed on an upper surface of the first molding layer, the lead, and the die pad, wherein the second molding layer encapsulates the semiconductor chip.

Some embodiments of the present disclosure further provide a method for forming a package structure. The method includes:

providing a carrier plate, wherein the carrier plate includes a plurality of discrete die pad regions, an isolation region surrounding each of die pads, and a lead region positioned between adjacent isolation regions;

forming a first isolation sacrificial layer covering an upper surface of the carrier plate including the isolation regions and an upper surface of the carrier plate including a portion of the lead regions, wherein a plurality of remaining lead regions not covered by the first isolation sacrificial layer are discrete;

forming a first metal layer on the upper surface of the carrier plate including the die pad region and the lead region on either side of the first isolation sacrificial layer, wherein an upper surface of the first metal layer is flush with an upper surface of the first isolation sacrificial layer;

forming a second isolation sacrificial layer on the upper surface of the first isolation sacrificial layer;

forming a first step sacrificial layer on a portion of the upper surface of the first metal layer in the lead region, wherein an upper surface of the first step sacrificial layer is flush with an upper surface of the second isolation sacrificial layer;

forming a second metal layer on the upper surface of the first metal layer on either side of the second isolation sacrificial layer and the first step sacrificial layer, wherein an upper surface of the second metal layer is flush with the upper surface of the second isolation sacrificial layer;

forming a third isolation sacrificial layer on the upper surface of the second isolation sacrificial layer;

forming a second step sacrificial layer on the upper surface of the first step sacrificial layer, wherein a width of the second step sacrificial layer is less than a width of the first step sacrificial layer, and an upper surface of the second step sacrificial layer is flush with an upper surface of the third isolation sacrificial layer;

forming a third metal layer on the upper surface of the second metal layer on either side of the third isolation sacrificial layer and the second step sacrificial layer, wherein an upper surface of the third metal layer is flush with the upper surface of the third isolation sacrificial layer, the first metal layer, the second metal layer, and the third metal layer of the die pad region constitute a die pad, and the first metal layer, the second metal layer, and the third metal layer of the lead region constitute a plurality of discrete initial leads;

removing the first step sacrificial layer and the second step sacrificial layer to form an inverted “T”-shaped trench;

removing the carrier plate to expose a lower surface of the first metal layer, and using a side surface on which the first metal layer is disposed as an upper surface of the die pad and an upper surface of the lead;

mounting a semiconductor chip onto an upper surface of the die pad, wherein the semiconductor chip is electrically connected to an upper surface of the initial lead;

forming a second molding layer wrapping the semiconductor chip and covering the upper surface of the initial lead and the upper surface of the die pad; and

dividing along a direction of a central axis of the inverted “T”-shaped trench to form several discrete package structures, wherein each of the initial leads is divided into two leads, the two leads are respectively disposed in two adjacent package structures, and correspondingly, the inverted “T”-shaped trench is divided into two halves to form a trench and a lateral hole communicated with the trench.

Some embodiments of the present disclosure further provide a method for forming a package structure. The method includes:

providing a metal frame, wherein the metal frame includes several discrete die pads and a plurality of discrete initial leads disposed on either side of or around the die pads, each of the initial leads including an upper surface and a lower surface that are opposite to each other, an initial trench extending through a portion of the lower surface of the initial lead, wherein a first molding layer is filled between the initial leads and between the initial lead and the die pad;

etching the initial lead from a bottom corner of the initial trench towards the die pad, and forming a lateral hole communicated with the initial trench in the initial lead;

mounting a semiconductor chip onto an upper surface of the die pad, wherein the semiconductor chip is electrically connected to an upper surface of the initial lead;

forming a second molding layer on an upper surface of the first molding layer, the upper surface of the initial lead, and the upper surface of the die pad; and

dividing along a direction of a central axis of the initial trench to form several discrete package structures, wherein each of the initial leads is divided into two leads, the two leads are respectively disposed in adjacent two of the package structures, and correspondingly the initial trench is divided into two trenches, each of the trenches being communicated with a corresponding lateral hole.

### BRIEF DESCRIPTION OF THE DRAWINGS

FIG. 1 is a schematic structural diagram of a package structure according to some embodiments of the present disclosure;

FIG. 2 is a schematic structural diagram of a package structure according to some embodiments of the present disclosure;

FIG. 3 is a process diagram of providing a carrier plate in a process for forming a package structure according to some embodiments of the present disclosure;

FIG. 4 is a schematic sectional view taken along an A-B direction in FIG. 3;

FIG. 5 is a process diagram of forming a first isolation sacrificial layer covering an upper surface of a carrier plate including isolation regions and an upper surface of a carrier plate including a portion of lead regions in a process for forming a package structure according to some embodiments of the present disclosure;

FIG. 6 is a schematic sectional view taken along an A-B direction in FIG. 5;

FIG. 7 is a process diagram of forming a first metal layer on an upper surface of a carrier plate including die pad regions and lead regions on either side of a first isolation sacrificial layer in a process for forming a package structure according to some embodiments of the present disclosure;

FIG. 8 is a process diagram of forming a second isolation sacrificial layer on an upper surface of a first isolation sacrificial layer in a process for forming a package structure according to some embodiments of the present disclosure;

FIG. 9 is a process diagram of forming a second metal layer on an upper surface of a first metal layer on either side of a second isolation sacrificial layer and a first step sacrificial layer in a process for forming a package structure according to some embodiments of the present disclosure;

FIG. 10 is a process diagram of forming a third isolation sacrificial layer on an upper surface of a second isolation sacrificial layer in a process for forming a package structure according to some embodiments of the present disclosure;

FIG. 11 is a process diagram of forming a third metal layer on an upper surface of a second metal layer on either side of a third isolation sacrificial layer and a second step sacrificial layer in a process for forming a package structure according to some embodiments of the present disclosure;

FIG. 12 is a process diagram of removing a first isolation sacrificial layer, a second isolation sacrificial layer, and a third isolation sacrificial layer in a process for forming a package structure according to some embodiments of the present disclosure;

FIG. 13 is a process diagram of removing a first step sacrificial layer and a second step sacrificial layer in a process for forming a package structure according to some embodiments of the present disclosure;

FIG. 14 is a process diagram of mounting a semiconductor chip onto an upper surface of a die pad in a process for forming a package structure according to some embodiments of the present disclosure;

FIG. 15 is a process diagram of forming several discrete package structures in a process for forming a package structure according to some embodiments of the present disclosure;

FIG. 16 is a process diagram of providing a metal frame in a process for forming a package structure according to some embodiments of the present disclosure;

FIG. 17 is a process diagram of forming a protective sidewall on a sidewall surface of an initial trench in a process for forming a package structure according to some embodiments of the present disclosure;

FIG. 18 is a process diagram of etching an initial lead from a bottom corner of an initial trench towards a die pad in a process for forming a package structure according to some embodiments of the present disclosure;

FIG. 19 is a process diagram of mounting a semiconductor chip onto an upper surface of a die pad in a process for forming a package structure according to some embodiments of the present disclosure;

FIG. 20 is a process diagram of forming several discrete package structures in a process for forming a package structure according to some embodiments of the present disclosure.

### DETAILED DESCRIPTION

The specific embodiments of the present disclosure are described in detail hereinafter with reference to the accompanying drawings. In the description of the embodiments of the present disclosure, for ease of illustration, the schematic structural views are not partially enlarged according to a typical scale, and the schematic views are given for exemplary purpose only, which do not limit the protection scope of the present disclosure. In addition, in practice, a three-dimension spatial size in terms of length, width, and depth needs to be included.

A package structure and a method for forming the same are provided in the embodiments of the present disclosure. The package structure includes: a die pad; a plurality of discrete leads disposed on either side of or around the die pad, wherein each of the leads includes an upper surface and a lower surface that are opposite to each other, a trench extending through a portion of the lower surface and a portion of an outer sidewall surface of the lead being formed in a region, away from the die pad, of the lead, a lateral hole being formed in the lead on a side surface of the trench, the lateral hole being communicated with the trench to form a step; a first molding layer filling the gaps between the leads and the die pad; a semiconductor chip disposed on an upper surface of the die pad, wherein the semiconductor chip is electrically connected to the upper surface of the lead; and a second molding layer disposed on an upper surface of the first molding layer, the lead, and the die pad, wherein the second molding layer encapsulates the semiconductor chip. With the lateral hole, the area or space of the step is increased, such that in the case that the package structure according to the present disclosure is soldered to the corresponding substrate (upper substrate), the space for soldering (for example, tin solder) at the step on the side surface of the lead is increased, and hence the coverage (or wettability) of the solder on the side surface of the lead is increased. In this way, whether the package structure according to the present disclosure is well soldered to the substrate may be more easily observed from the side.

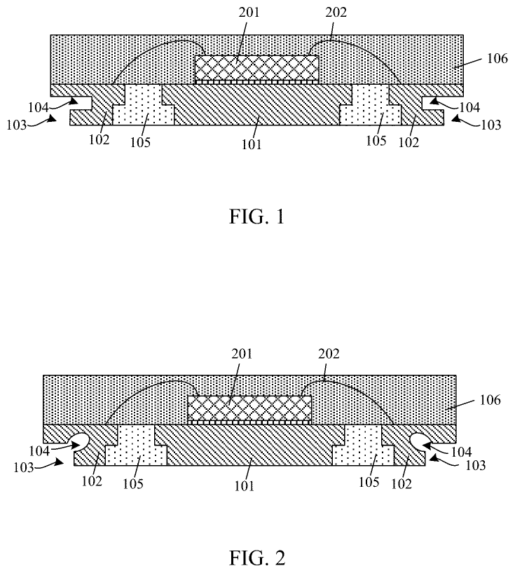

Some embodiments of the present disclosure provide a package structure. Referring to FIG. 1, the package structure includes:

a die pad 101;

a plurality of discrete leads 102 disposed on either side of or around the die pad 101, wherein each of the leads 102 includes an upper surface and a lower surface that are opposite to each other, a trench 103 extending through a portion of the lower surface and a portion of an outer sidewall surface of the lead 102 being formed in a region, away from the die pad 101, of the lead 102 to form a step, a lateral hole 104 being formed in the lead 102 on a side surface of the step, the lateral hole 104 being communicated with the trench 104;

a first molding layer 105 filling the gaps between the leads 102 and the die pad 101;

a semiconductor chip 201 disposed on an upper surface of the die pad 101, wherein the semiconductor chip 201 is electrically connected to the upper surface of the lead 102; and

a second molding layer 106 disposed on an upper surface of the first molding layer 105, the lead 102, and the die pad 101, wherein the second molding layer 106 encapsulates the semiconductor chip 201.

Specifically, the die pad 101 is configured to support the semiconductor chip 201. The die pad 101 may be made of a material the same as or different from the material of the lead 102. in some embodiments, the die pad 101 is made of a metal material or insulating material. The metal may be one or more of W, Al, Cu, Ti, Ag, Au, Pt, or Ni. The insulating material may be an inorganic insulating material or organic insulating material. The inorganic insulating material may be one or more of silicon oxide, silicon nitride, silicon oxynitride, silicon carbide, or silicon carbonitride. The organic insulating material may be epoxy resin, polyimide resin, benzocyclobutene resin, or polybenzoxazole resin; or may be polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol.

In some embodiments, a depth of the trench is less than a thickness of the lead, and an aperture size of the lateral hole is less than the depth of the trench.

In some embodiments, the trench is square, and the lateral hole extends in the lead from a bottom corner of the trench towards the die pad.

In some embodiments, the lateral hole extends in the lead from the bottom corner of the trench towards the die pad in a pattern of being parallel to the upper surface of the lead or forming an angle with the upper surface of the lead.

In some embodiments, the lateral hole is square, circular, or elliptical.

In some embodiments, the die pad is made of a same or different materials from the lead.

In some embodiments, the semiconductor chip includes a functional surface and a back surface that are opposite to each other, wherein a pad is arranged on the functional surface, and the back surface of the semiconductor chip is attached to the upper surface of the die pad, the pad on the functional surface of the semiconductor chip being electrically connected to the lead via a wire.

In some embodiments, the semiconductor chip includes a functional surface and a back surface that are opposite to each other, wherein a solder bump protrudes from the functional surface, and the semiconductor chip is flip-mounted over the upper surface of the die pad, the solder bump on the functional surface of the semiconductor chip being soldered to the lead.

In some embodiments, a size of an upper portion of the die pad 101 is larger than a size of a lower portion thereof, or the size of the upper portion is the same as or slightly different from the size of the lower portion.

A plurality of leads 102 are disposed on either side of or around the die pad 101. The leads 102 are discrete from each other. In the case that the die pad 101 is made of a metal, no contact is present between the lead 102 and the die pad 101, which are separated by the first molding layer 105. The lead 102 is made of a metal. In a specific embodiment, the lead 102 may be made of one or more of W, Al, Cu, Ti, Ag, Au, Pt, or Ni.

Each of the leads 102 includes an upper surface and a lower surface that are opposite to each other. The upper surface of the lead 102 is connected to the semiconductor chip 201, and the lower surface of the lead 102 serves as a port for connecting the package structure to an external substrate, for example, a PCB substrate. A trench 103 extending through a portion of the lower surface and a portion of the outer sidewall surface of the lead 102 is formed in a region, away from the die pad 101, of the lead 102. A lateral hole 104 is further formed in the lead 102 on a side surface of the trench 103. The lateral hole 104 is communicated with the trench 103 to form a step. With the lateral hole 104, the area or space of the step is increased, such that in the case that the package structure according to the present disclosure is soldered to the corresponding substrate (upper substrate), the space for solder (for example, tin solder) at the step on the side surface of the lead is increased, and hence the coverage (or wettability) of the solder on the side surface of the lead is increased. In this way, whether the package structure according to the present disclosure is well soldered to the substrate may be more easily observed from the side.

A depth of the trench 103 is less than a thickness of the lead 102, and an aperture size of the lateral hole 104 is less than the depth of the trench 103.

In some embodiments, the trench 103 is square, and the lateral hole 104 extends in the lead 102 from a bottom corner of the trench 103 towards the die pad 101.

In some embodiments, still referring to FIG. 1, the lateral hole 104 extends in the lead 102 from the bottom corner of the trench 103 towards the die pad 101 in a pattern of being parallel to the upper surface of the lead 102. The lateral hole 104 in this structure reduces the difficulty of applying solder while increasing the space for applying solder to the step. In this way, the solder coverage is further improved, and the process of fabricating the lateral hole 104 in this structure is relatively simple.

In some other embodiments, referring to FIG. 2, the lateral hole 104 extends in the lead 102 from the bottom corner of the trench 103 towards the die pad 101 in a pattern of forming an angle with the upper surface of the lead 102. The angle is an angle formed between the central axis of the lateral hole 104 and the upper surface of the lead, and the angle ranges from 30 degrees to 60 degrees. The lateral hole 104 in this structure reduces the difficulty of applying solder while increasing the space for applying solder to the step. In this way, the solder coverage is further improved, and the process of fabricating the lateral hole 104 in this structure is relatively simple.

In some embodiments, the lateral hole 104 is square (referring to FIG. 1), circular, or elliptical (referring to FIG. 2).

In some embodiments, referring to FIG. 1 and FIG. 2, the semiconductor chip 201 includes a functional surface and a back surface that are opposite to each other. A pad is arranged on the functional surface (not illustrated), and the pad is made of one or more of aluminum, nickel, tin, tungsten, platinum, copper, titanium, chromium, tantalum, gold, or silver. The pad is electrically connected to an integrated circuit. The back surface of the semiconductor chip 201 is attached to the upper surface of the die pad 101. The pad on the functional surface of the semiconductor chip 201 is electrically connected to (the upper surface of) the lead 102 via a wire 202. The back surface of the semiconductor chip 201 is attached to the upper surface of the die pad 101 via an adhesive layer, wherein the adhesive layer includes an adhesive. The wire 202 is made of a metal.

In some embodiments, the semiconductor chip 201 may be a logic chip or a memory chip. In some embodiments, the logic chip may include a gate array, a cell-based array, an embedded array, an application-specific integrated circuit (ASIC), a field-programmable gate array (FPGA), a complex programmable logic device (CPLD), a central processing unit (CPU), a microprocessor units (MPU), a microcontroller unit (MCU), an integrated circuit (IC), an application processor (AP), a display driver IC (DDI), a radio frequency (RF) chip, a power management IC, or a complementary metal-oxide-semiconductor (CMOS) image sensor. In some embodiments, the memory chip may include a volatile memory chip, such as a dynamic random access memory (DRAM) or a static RAM (SRAM), or a non-volatile memory chip, such as a flash memory (Flash), a phase change RAM (PRAM), a magnetoresistive RAM (MRAM), a ferroelectric RAM (FeRAM) or a resistive RAM (ReRAM).

In some embodiments, the semiconductor chip 201 includes a functional surface and a back surface that are opposite to each other. A solder bump (not illustrated) protrudes from the functional surface, and the semiconductor chip is flip-mounted over the upper surface of the die pad 101. The solder bump on the functional surface of the semiconductor chip 201 is soldered to (the upper surface of) the lead 102. The solder bump may be a solder boss, or includes a metal bump and a solder boss on a top surface of the metal bump. In some embodiments, the metal bump is made of one or more of aluminum, nickel, tin, tungsten, platinum, copper, titanium, chromium, tantalum, gold, silver, and the solder bump is made of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The first molding layer 105 and the second molding layer 106 may be made of a same material or different materials. In a specific embodiment, the first molding layer 105 or the second molding layer 106 may be made of a silicon-based resin material, a thermoplastic resin material, a heat-cured resin material, or an ultraviolet-cured resin material.

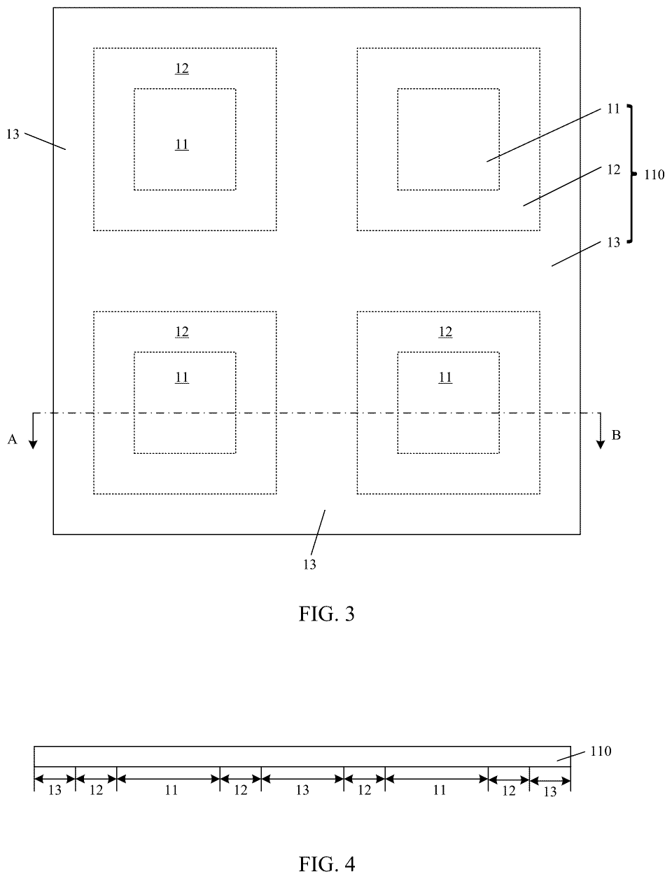

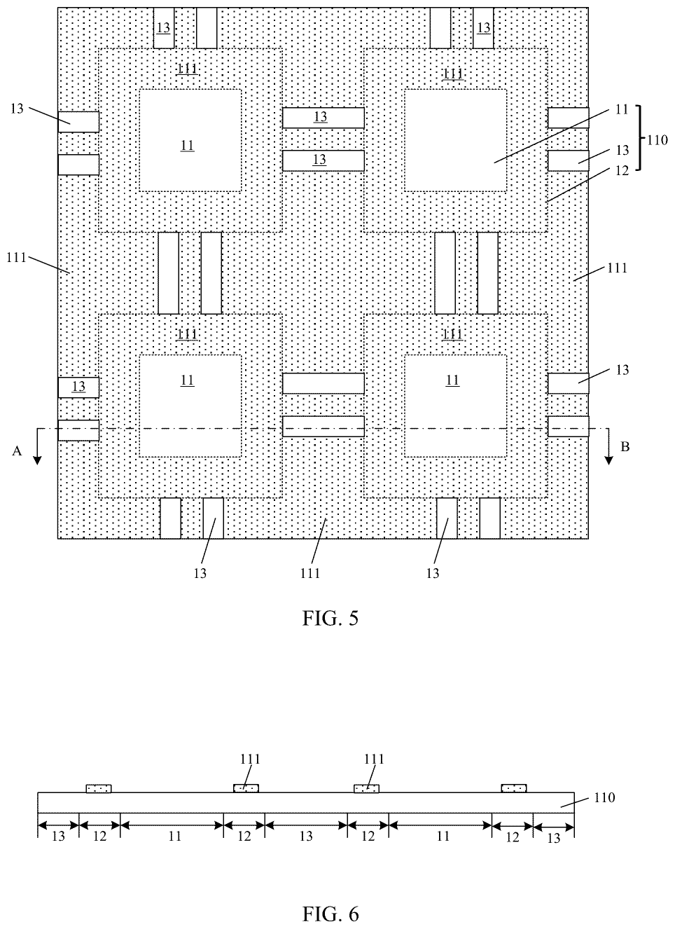

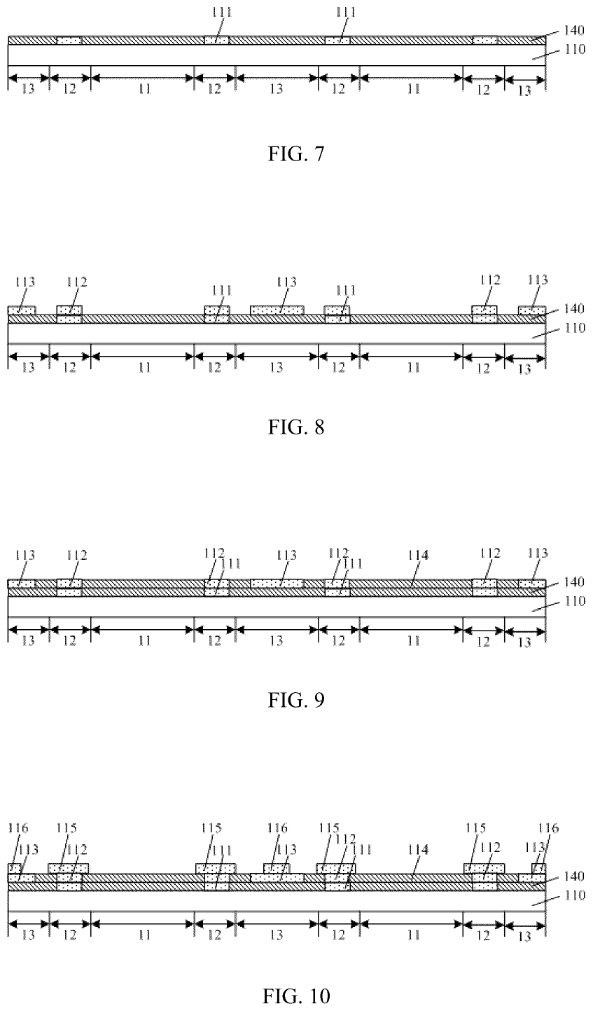

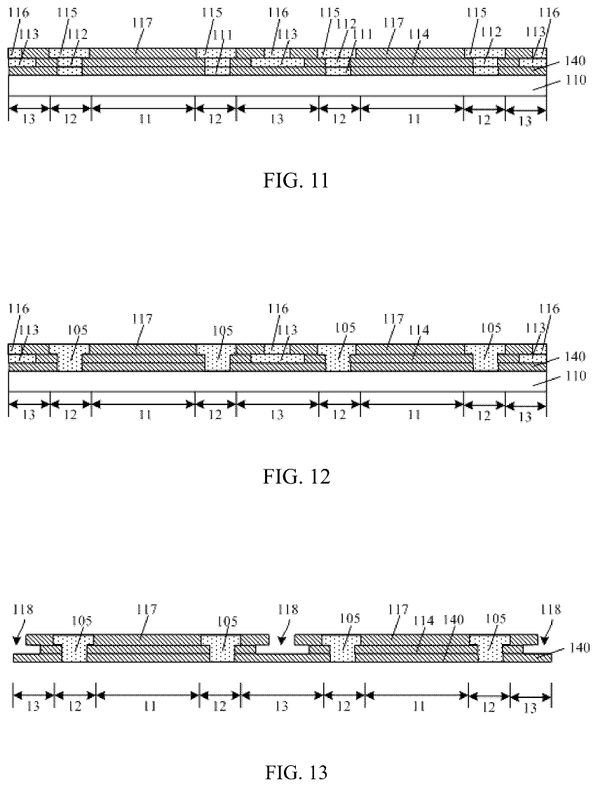

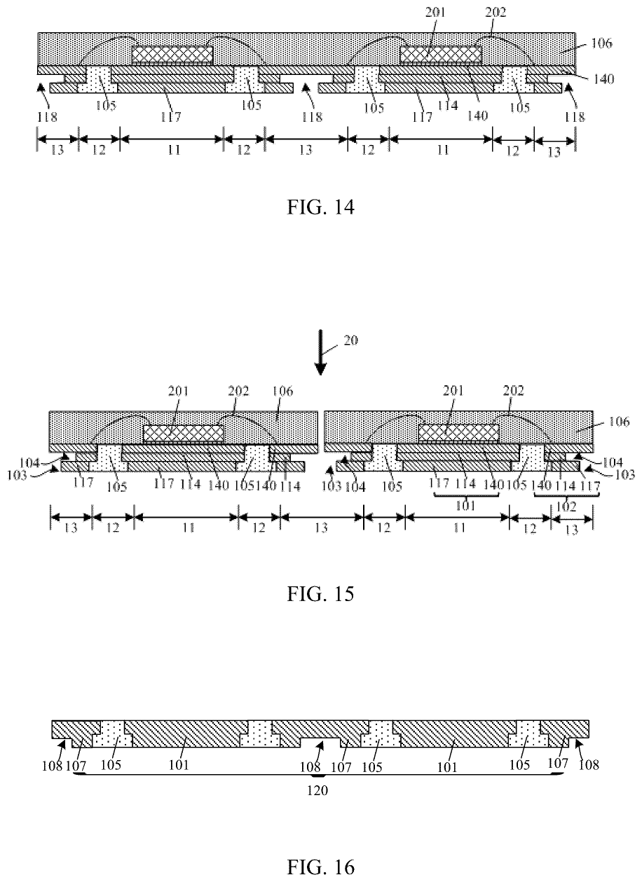

Some embodiments of the present disclosure provide a method for forming a package structure. Hereinafter, the method is described with reference to the accompanying drawings. Referring to FIG. 3 to FIG. 15, FIG. 3 is a process diagram of providing a carrier plate in a process for forming a package structure according to some embodiments of the present disclosure; FIG. 4 is a schematic sectional view taken along an A-B direction in FIG. 3; FIG. 5 is a process diagram of forming a first isolation sacrificial layer covering an upper surface of a carrier plate including isolation regions and an upper surface of a carrier plate including a portion of lead regions in a process for forming a package structure according to some embodiments of the present disclosure; FIG. 6 is a schematic sectional view taken along an A-B direction in FIG. 5; FIG. 7 is a process diagram of forming a first metal layer on an upper surface of a carrier plate including die pad regions and lead regions on either side of a first isolation sacrificial layer in a process for forming a package structure according to some embodiments of the present disclosure; FIG. 8 is a process diagram of forming a second isolation sacrificial layer on an upper surface of a first isolation sacrificial layer in a process for forming a package structure according to some embodiments of the present disclosure; FIG. 9 is a process diagram of forming a second metal layer on an upper surface of a first metal layer on either side of a second isolation sacrificial layer and a first step sacrificial layer in a process for forming a package structure according to some embodiments of the present disclosure; FIG. 10 is a process diagram of forming a third isolation sacrificial layer on an upper surface of a second isolation sacrificial layer in a process for forming a package structure according to some embodiments of the present disclosure; FIG. 11 is a process diagram of forming a third metal layer on an upper surface of a second metal layer on either side of a third isolation sacrificial layer and a second step sacrificial layer in a process for forming a package structure according to some embodiments of the present disclosure; FIG. 12 is a process diagram of removing a first isolation sacrificial layer, a second isolation sacrificial layer, and a third isolation sacrificial layer in a process for forming a package structure according to some embodiments of the present disclosure; FIG. 13 is a process diagram of removing a first step sacrificial layer and a second step sacrificial layer in a process for forming a package structure according to some embodiments of the present disclosure; FIG. 14 is a process diagram of mounting a semiconductor chip onto an upper surface of a die pad in a process for forming a package structure according to some embodiments of the present disclosure; and FIG. 15 is a process diagram of forming several discrete package structures in a process for forming a package structure according to some embodiments of the present disclosure.

Referring to FIG. 3 and FIG. 4, FIG. 4 is a schematic sectional view taken along an A-B direction in FIG. 3. As illustrated in FIG. 4, a carrier plate 110 is provided. The carrier plate 110 includes a plurality of discrete die pad regions 11, an isolation region 12 surrounding each of die pad regions 11, and a lead region 13 positioned between adjacent isolation regions 12.

The carrier plate 110 may serve as a carrier for subsequent processes. In some embodiments, the carrier plate 110 may be a resin carrier plate, a ceramic carrier plate, a glass carrier plate, a silicon carrier plate, or a metal carrier plate.

The carrier plate 110 includes an upper surface and a lower surface that are opposite to each other. In some embodiments, a conductive layer may also be formed on the upper surface of the carrier plate 110 (not illustrated). The conductive layer may serve as a conductive layer for subsequently forming the first metal layer, the second metal layer, and the third metal layer by an electroplating process. The conductive layer may be made of one or more of Al, Cu, Ag, Au, Pt, Ni, Ti, TiN, TaN, Ta, TaC, TaSiN, W, WN, or WSi.

The die pad region 11 is subsequently configured to form a die pad thereon, the isolation region 12 is subsequently configured to form an isolation layer or a molding layer thereon, and the lead region 13 is subsequently configured to form a lead thereon. In some embodiments, the plurality of discrete die pad regions 11 on the carrier plate 110 may be arranged in an array. The die pad regions 11 may be formed in a rectangular or square shape. The isolation region 12 is formed in a circular shape, and each of the isolation regions 12 surrounds the corresponding die pad region 11. The lead region 13 is positioned between adjacent isolation regions 12, and the lead region is in the form of a grid. It should be noted that the number of die pad regions 11 and isolation regions 12 illustrated in FIG. 4 is 4, which is only as an example, and the number of die pad regions 11 and isolation regions 12 should not limit the protection scope of the present disclosure. In some other embodiments, the number of die pad regions 11 and the number of isolation regions 12 may also be defined to other values rather than 4.

Referring to FIG. 5 and FIG. 6, FIG. 6 is a schematic sectional view taken along an A-B direction in FIG. 5. As illustrated in FIG. 6, a first isolation sacrificial layer 111 covering an upper surface of the carrier plate 110 in the isolation regions 12 and an upper surface of a portion of the lead regions 13, wherein a plurality of remaining lead regions 13 not covered by the first isolation sacrificial layer 111 are discrete.

The first isolation sacrificial layer 111 defines a position for subsequently forming the first metal layer. In some embodiments, a plurality of regions in the lead regions 13 that are not covered by the first isolation sacrificial layer 111 are discrete from each other, and the plurality of regions that are not covered by the first isolation sacrificial layer 111 may be subsequently correspondingly formed into a plurality of discrete initial leads. In FIG. 5, eight lead regions 13 that are not covered by the first isolation sacrificial layer 11 are exemplarily illustrated around each of the isolation regions 12. In some other embodiments, the number of lead regions 13 that are not covered by the first isolation sacrificial layer 111 around each of the isolation regions 12 may also be other values.

In some embodiments, the method further includes: removing the first isolation sacrificial layer, the second isolation sacrificial layer, and the third isolation sacrificial layer; and filling a molding material at positions where the first isolation sacrificial layer, the second isolation sacrificial layer, and the third isolation sacrificial layer are removed to form a first molding layer.

In some embodiments, the first isolation sacrificial layer, the second isolation sacrificial layer, and the third isolation sacrificial layer are photosensitive polymers, and the first isolation sacrificial layer, the second isolation sacrificial layer, and the third isolation sacrificial layer that are cured are directly used as a first molding layer.

In some embodiments, a width of the second isolation sacrificial layer or the third isolation sacrificial layer is greater than or equal to a width of the first isolation sacrificial layer.

In some embodiments, the semiconductor chip includes a functional surface and a back surface that are opposite to each other, wherein a pad is arranged on the functional surface, and the back surface of the semiconductor chip is attached to the upper surface of the die pad, the pad on the functional surface of the semiconductor chip being electrically connected to the lead via a wire.

In some embodiments, the first isolation sacrificial layer 111 is made of a photosensitive polymer (for example, photoresist or photosensitive resin), and the photosensitive polymer is patterned by an exposure and development process to form the first step sacrificial layer 111. In some other embodiments, the first isolation sacrificial layer 111 may also be also be made of an inorganic isolation material, for example, silicon oxide or silicon nitride.

Referring to FIG. 7, a first metal layer 140 is formed on an upper surface of the carrier plate 110 including the die pad regions 11 and the lead regions 13 on either side of the first isolation sacrificial layer 111. An upper surface of the first metal layer 140 is flush with an upper surface of the first isolation sacrificial layer 111.

The first metal layer 140 may be made of W, Al, Cu, Ti, Ag, Au, Pt, or Ni.

In some embodiments, the first metal layer 140 is formed by an electroplating process. In some other embodiments, the first metal layer 140 may also be formed by a sputtering processor or a chemical mechanical polishing process.

Referring to FIG. 8, a second isolation sacrificial layer 112 is formed on the upper surface of the first isolation sacrificial layer 111; and a first step sacrificial layer 113 is formed on a portion of the upper surface of the first metal layer 140 in the lead region 13. An upper surface of the first step sacrificial layer 113 is flush with an upper surface of the second isolation sacrificial layer 112.

In some embodiments, the second isolation sacrificial layer 112 and the first step sacrificial layer 113 may be both made of a photosensitive polymer, for example, photoresist or photosensitive resin. In some other embodiments, the second isolation sacrificial layer 112 and the first step sacrificial layer 113 may also be both made of an inorganic isolation material, for example, silicon oxide or silicon nitride.

In some embodiments, a width of the second isolation sacrificial layer 112 is greater than or equal to a width of the first isolation sacrificial layer 111.

Referring to FIG. 9, a second metal layer 114 is formed on the upper surface of the first metal layer 140 on either side of the second isolation sacrificial layer 112 and the first step sacrificial layer 113. An upper surface of the second metal layer 114 is flush with the upper surface of the second isolation sacrificial layer 112.

The second metal layer 114 may be made of W, Al, Cu, Ti, Ag, Au, Pt, or Ni.

In some embodiments, the second metal layer 114 is formed by an electroplating process. In some other embodiments, the second metal layer 114 may also be formed by a sputtering processor or a chemical mechanical polishing process.

Referring to FIG. 10, a third isolation sacrificial layer 115 is formed on the upper surface of the second isolation sacrificial layer 112; and a second step sacrificial layer 116 is formed on the upper surface of the first step sacrificial layer 113. A width of the second step sacrificial layer 116 is less than a width of the first step sacrificial layer 113, and an upper surface of the second step sacrificial layer 116 is flush with an upper surface of the third isolation sacrificial layer 115.

In some embodiments, the second step sacrificial layer 116 and the third isolation sacrificial layer 115 may be both made of a photosensitive polymer, for example, photoresist or photosensitive resin. In some other embodiments, the second step sacrificial layer 116 and the third isolation sacrificial layer 115 may also be both made of an inorganic isolation material, for example, silicon oxide or silicon nitride.

In some embodiments, a width of the third isolation sacrificial layer 115 is greater than or equal to the width of the first isolation sacrificial layer 111.

Referring to FIG. 11, a third metal layer 117 is formed on the upper surface of the second metal layer 114 on either side of the third isolation sacrificial layer 115 and the second step sacrificial layer 116. An upper surface of the third metal layer 117 is flush with the upper surface of the third isolation sacrificial layer 115, the first metal layer 140, the second metal layer 114, and the third metal layer 117 of the die pad region 11 constitute a die pad, and the first metal layer 140, the second metal layer 114, and the third metal layer 117 of the lead region 13 constitute a plurality of discrete initial leads.

The third metal layer 117 may be made of W, Al, Cu, Ti, Ag, Au, Pt, or Ni.

In some embodiments, the third metal layer 117 is formed by an electroplating process. In some other embodiments, the third metal layer 117 may also be formed by a sputtering processor or a chemical mechanical polishing process.

Referring to FIG. 12, the first isolation sacrificial layer 111, the second isolation sacrificial layer 112, and the third isolation sacrificial layer 115 are removed (referring to FIG. 11); and a molding material is filled at positions where the first isolation sacrificial layer 111, the second isolation sacrificial layer 112, and the third isolation sacrificial layer 115 are removed to form a first molding layer 105. The first molding layer 105 is made of resin, and the first molding layer 105 is formed by an injection molding process or a transfer molding process.

The first isolation sacrificial layer 111, the second isolation sacrificial layer 112, and the third isolation sacrificial layer 115 may be removed by an etching process.

In some other embodiments, in the case that the first isolation sacrificial layer 111, the second isolation sacrificial layer 112, and the third isolation sacrificial layer 115 are photosensitive polymers, the first isolation sacrificial layer, the second isolation sacrificial layer, and the third isolation sacrificial layer that are cured are directly used as a first molding layer 105.

In some embodiments, the first isolation sacrificial layer 111, the second isolation sacrificial layer 112, and the third isolation sacrificial layer 115 may be removed; or the first step sacrificial layer 113 and the second step sacrificial layer 116 are simultaneously removed.

Referring to FIG. 13, the first step sacrificial layer 113 and the second step sacrificial layer 116 (referring to FIG. 12) are removed to form an inverted “T”-shaped trench 118; and the carrier plate 110 (referring to FIG. 13) is removed to expose a lower surface of the first metal layer 140, and a side surface on which the first metal layer 140 is disposed is used as an upper surface of the die pad and an upper surface of the lead.

The first step sacrificial layer 113 and the second step sacrificial layer 116 may be removed by an etching process.

Referring to FIG. 14, a semiconductor chip 201 is mounted onto an upper surface of the die pad, wherein the semiconductor chip 201 is electrically connected to an upper surface of the initial lead; and a second molding layer 106 wrapping the semiconductor chip 201 and covering an upper surface of the initial lead and the die pad is formed.

The semiconductor chip 201 includes a functional surface and a back surface that are opposite to each other. A pad is arranged on the functional surface (not illustrated). The back surface of the semiconductor chip 201 is attached to the upper surface of the die pad (or the surface of the first metal layer 140 in the die pad region 11). A wire 202 is formed by a bonding process, and the pad on the semiconductor chip 201 is electrically connected to the initial lead (or electrically connected to the first metal layer 140 in a lead region 13) via the wire 202.

The second molding layer 106 is made of resin, and the second molding layer 106 is formed by an injection molding process or a transfer molding process.

Referring to FIG. 15, the structure is divided along a direction of a central axis of the inverted “T”-shaped trench 108 (referring to FIG. 14) to form several discrete package structures. Each of the initial leads is divided into two leads 103, the two leads 103 are respectively disposed in two adjacent package structures, and correspondingly, the inverted “T”-shaped trench 108 is divided into two halves to form a trench 103 and a lateral hole 104 communicated with the trench 103.

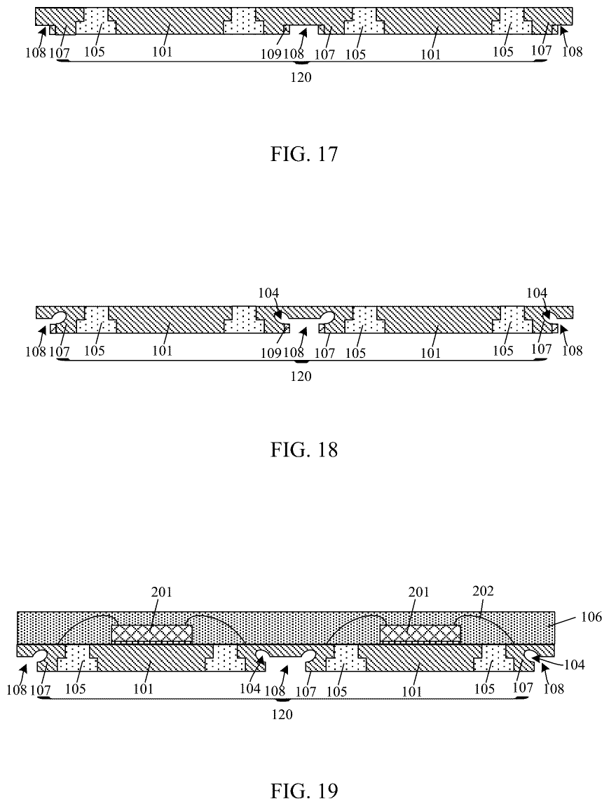

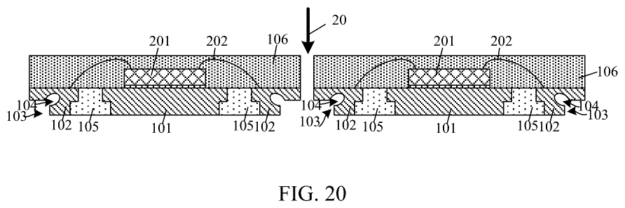

Some embodiments of the present disclosure further provide a method for forming a package structure. Referring to FIG. 16 to FIG. 20, FIG. 16 is a process diagram of providing a metal frame in a process for forming a package structure according to some embodiments of the present disclosure; FIG. 17 is a process diagram of forming a protective sidewall on a sidewall surface of an initial trench in a process for forming a package structure according to some embodiments of the present disclosure; FIG. 18 is a process diagram of etching an initial lead from a bottom corner of an initial trench towards a die pad in a process for forming a package structure according to some embodiments of the present disclosure; FIG. 19 is a process diagram of mounting a semiconductor chip onto an upper surface of a die pad in a process for forming a package structure according to some embodiments of the present disclosure; and FIG. 20 is a process diagram of forming several discrete package structures in a process for forming a package structure according to some embodiments of the present disclosure.

Referring to FIG. 6, a metal frame 120 is provided, wherein the metal frame 120 includes several discrete die pads 101 and a plurality of discrete initial leads 107 disposed on either side of or around the die pads 101. Each of the initial leads 107 includes an upper surface and a lower surface that are opposite to each other. An initial trench 108 extending through a portion of the lower surface of the initial lead 107 is formed in the initial lead 107. A first molding layer 105 is filled between the initial leads 107 and between the initial lead 107 and the die pad 101.

In some embodiments, the initial lead is etched from the bottom corner of the initial trench towards the die pad by an isotropic dry etching process or isotropic wet etching process.

In some embodiments, prior to etching the initial lead from a bottom corner of the initial trench towards the die pad, the method further includes: forming a protective sidewall on a sidewall surface of the initial trench.

In some embodiments, the initial trench 108 is square, and a depth of the initial trench 108 is less than a thickness of the initial lead 107.

In some embodiments, referring to FIG. 17, a protective sidewall 109 is formed on a sidewall surface of the initial trench 108.

The protective sidewall 109 protects a sidewall of the initial trench 108 from being etched during etching the initial lead 107 from a bottom corner of the initial trench 108 towards the die pad 101.

The protective sidewall 109 may be made of one or more of silicon oxide, silicon nitride, silicon oxynitride, silicon carbide, or silicon carbonitride.

Referring to FIG. 18, the initial lead 107 is etched from the bottom corner of the initial trench 108 towards the die pad 101, and a lateral hole 104 communicated with the initial trench 108 is formed in the initial lead 107.

The initial lead 107 is etched from the bottom corner of the initial trench 108 towards the die pad 101 by an isotropic dry etching process or isotropic wet etching process.

In some embodiments, during etching the initial lead 107 from the bottom corner of the initial trench 108 towards the die pad 101, the initial lead 107 at a bottom of the initial trench 108 may also be etched and a portion of the initial lead 107 may be removed, such that the depth of the initial trench 108 is increased.

Referring to FIG. 19, a semiconductor chip 201 is mounted onto an upper surface of the die pad 101, wherein the semiconductor chip 201 is electrically connected to an upper surface of the initial lead 107; and a second molding layer 106 molding the semiconductor chip 201 is formed on the upper surface of the first molding layer 105, the initial lead 107, and the die pad 101.

Referring to FIG. 20, the structure is divided along a direction of a central axis of the initial trench 108 (referring to FIG. 19) to form several discrete package structures. Each of the initial leads 107 (referring to FIG. 19) is divided into two leads 102, the two leads 102 are respectively disposed in two adjacent package structures, and correspondingly the initial trench 108 is divided into two trenches 103. Each of the trenches 103 is communicated with a corresponding lateral hole 104.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Although the present disclosure has been disclosed above with reference to preferred embodiments, these embodiments are not intended to limit the present disclosure but illustrate the present disclosure. Without departing from the spirit and scope of the present disclosure, any person skilled in the art may make possible variations and modifications to the technical solutions based on the method and technical content disclosed herein in this literature. Therefore, any content without departing from the technical solutions of the present disclosure and any simple variation, equivalent replacement and modification made based on the technical essence of the present disclosure shall fall within the protection scope defined by the technical solutions of the present disclosure.

What is claimed is:

1. A package structure, comprising:
a die pad;
a plurality of discrete leads disposed on either side of or around the die pad, wherein each of the leads comprises an upper surface and a lower surface that are opposite to each other, a trench extending through a portion of the lower surface and a portion of an outer sidewall surface of a lead being formed in a region, away from the die pad, of the lead, a lateral hole being formed in the lead on a side surface of the trench, and the lateral hole being communicated with the trench to form a step;
a first molding layer filling the gaps between the leads and the die pad;
a semiconductor chip disposed on an upper surface of the die pad, wherein the semiconductor chip is electrically connected to an upper surface of the lead; and
a second molding layer disposed on an upper surface of the first molding layer, the lead, and the die pad, wherein the second molding layer encapsulates the semiconductor chip.

2. The package structure according to claim 1, wherein a depth of the trench is less than a thickness of the lead, and an aperture size of the lateral hole is less than the depth of the trench.

3. The package structure according to claim 1, wherein the trench is square, and the lateral hole extends in the lead from a bottom corner of the trench towards the die pad.

4. The package structure according to claim 3, wherein the lateral hole extends in the lead from the bottom corner of the trench towards the die pad in a pattern of being parallel to the upper surface of the lead or forming an angle with the upper surface of the lead.

5. The package structure according to claim 3, wherein the lateral hole is square, circular, or elliptical.

6. The package structure according to claim 1, wherein the die pad is made of same or different materials from the lead.

7. The package structure according to claim 1, wherein the semiconductor chip comprises a functional surface and a back surface that are opposite to each other, wherein a pad is arranged on the functional surface, and the back surface of the semiconductor chip is attached to the upper surface of the die pad, the pad on the functional surface of the semiconductor chip being electrically connected to the lead via a wire.

8. The package structure according to claim 1, wherein the semiconductor chip comprises a functional surface and a back surface that are opposite to each other, wherein a solder bump protrudes from the functional surface, and the semiconductor chip is flip-mounted over the upper surface of the die pad, the solder bump on the functional surface of the semiconductor chip being soldered to the lead.

9. The package structure according to claim 2, wherein the trench is square, and the lateral hole extends in the lead from a bottom corner of the trench towards the die pad.

10. The package structure according to claim 6, wherein the semiconductor chip comprises a functional surface and a back surface that are opposite to each other, wherein a pad is arranged on the functional surface, and the back surface of the semiconductor chip is attached to the upper surface of the die pad, the pad on the functional surface of the semiconductor chip being electrically connected to the lead via a wire.

11. The package structure according to claim 6, wherein the semiconductor chip comprises a functional surface and a back surface that are opposite to each other, wherein a solder bump protrudes from the functional surface, and the semiconductor chip is flip-mounted over the upper surface of the die pad, the solder bump on the functional surface of the semiconductor chip being soldered to the lead.

12. A method for forming a package structure, comprising:
providing a carrier plate, wherein the carrier plate comprises a plurality of discrete die pad regions, an isolation region surrounding each of the plurality of discrete die pad regions, and a lead region positioned between adjacent isolation regions;
forming a first isolation sacrificial layer covering an upper surface of the carrier plate including isolation regions and an upper surface of the carrier plate including a portion of lead regions, wherein a plurality of remaining lead regions not covered by the first isolation sacrificial layer are discrete;
forming a first metal layer on the upper surface of the carrier plate including a die pad region and the lead region on either side of the first isolation sacrificial layer, wherein an upper surface of the first metal layer is flush with an upper surface of the first isolation sacrificial layer;
forming a second isolation sacrificial layer on the upper surface of the first isolation sacrificial layer;
forming a first step sacrificial layer on a portion of the upper surface of the first metal layer in the lead region, wherein an upper surface of the first step sacrificial layer is flush with an upper surface of the second isolation sacrificial layer;
forming a second metal layer on the upper surface of the first metal layer on either side of the second isolation sacrificial layer and the first step sacrificial layer, wherein an upper surface of the second metal layer is flush with the upper surface of the second isolation sacrificial layer;
forming a third isolation sacrificial layer on the upper surface of the second isolation sacrificial layer;
forming a second step sacrificial layer on the upper surface of the first step sacrificial layer, wherein a width of the second step sacrificial layer is less than a width of the first step sacrificial layer, and an upper surface of the second step sacrificial layer is flush with an upper surface of the third isolation sacrificial layer;
forming a third metal layer on the upper surface of the second metal layer on either side of the third isolation sacrificial layer and the second step sacrificial layer, wherein an upper surface of the third metal layer is flush with the upper surface of the third isolation sacrificial layer, the first metal layer, the second metal layer, and the third metal layer of the die pad region constitute a die pad, and the first metal layer, the second metal layer, and the third metal layer of the lead region constitute a plurality of discrete initial leads;
removing the first step sacrificial layer and the second step sacrificial layer to form an inverted “T”-shaped trench;
removing the carrier plate to expose a lower surface of the first metal layer, and using a side surface on which the first metal layer is disposed as an upper surface of the die pad and an upper surface of an initial lead;
mounting a semiconductor chip onto the upper surface of the die pad, wherein the semiconductor chip is electrically connected to the upper surface of the initial lead;
forming a second molding layer wrapping the semiconductor chip and covering the upper surface of the initial lead and the upper surface of the die pad; and
dividing along a direction of a central axis of the inverted “T”-shaped trench to form several discrete package structures, wherein each of the plurality of discrete initial leads is divided into two leads, the two leads are respectively disposed in two adjacent package structures, and correspondingly, the inverted “T”-shaped trench is divided into two halves to form a trench and a lateral hole communicated with the trench.

13. The method according to claim 12, further comprising: removing the first isolation sacrificial layer, the second isolation sacrificial layer, and the third isolation sacrificial layer; and filling a molding material at positions where the first isolation sacrificial layer, the second isolation sacrificial layer, and the third isolation sacrificial layer are removed to form a first molding layer.

14. The method according to claim 12, wherein the first isolation sacrificial layer, the second isolation sacrificial layer, and the third isolation sacrificial layer are photosensitive polymers, and the first isolation sacrificial layer, the second isolation sacrificial layer, and the third isolation sacrificial layer that are cured are directly used as a first molding layer.

15. The method according to claim 12, wherein a width of the second isolation sacrificial layer or the third isolation sacrificial layer is greater than or equal to a width of the first isolation sacrificial layer.

16. The method according to claim 12, wherein the semiconductor chip comprises a functional surface and a back surface that are opposite to each other, wherein a pad is arranged on the functional surface, and the back surface of the semiconductor chip is attached to the upper surface of the die pad, the pad on the functional surface of the semiconductor chip being electrically connected to a lead via a wire.

17. A method for forming a package structure, comprising:
providing a metal frame, wherein the metal frame comprises several discrete die pads and a plurality of discrete initial leads disposed on either side of or around the discrete die pads, each of the plurality of discrete initial leads comprising an upper surface and a lower surface that are opposite to each other, an initial trench extending through a portion of the lower surface of an initial lead, wherein a first molding layer is filled between the plurality of discrete initial leads and between the initial lead and a die pad;
etching the initial lead from a bottom corner of the initial trench towards the die pad, and forming a lateral hole communicated with the initial trench in the initial lead;
mounting a semiconductor chip onto an upper surface of the die pad, wherein the semiconductor chip is electrically connected to an upper surface of the initial lead;
forming a second molding layer on an upper surface of the first molding layer, the upper surface of the initial lead, and the upper surface of the die pad; and
dividing along a direction of a central axis of the initial trench to form several discrete package structures, wherein each of the plurality of discrete initial leads is divided into two leads, the two leads are respectively disposed in adjacent two of the discrete package structures, and correspondingly the initial trench is divided into two trenches, each of the trenches being communicated with a corresponding lateral hole.

18. The method according to claim 17, wherein the initial lead is etched from the bottom corner of the initial trench towards the die pad by an isotropic dry etching process or an isotropic wet etching process.

19. The method according to claim 18, wherein prior to etching the initial lead from the bottom corner of the initial trench towards the die pad, the method further comprises: forming a protective sidewall on a sidewall surface of the initial trench.
